(19) United States
(12) Patent Application Publication
(10) Pub. No.: US 2025/0241183 A1
(43) Pub. Date: Jul. 24, 2025

(54) DISPLAY DEVICE

(71) Applicant: Japan Display Inc., Tokyo (JP)

(72) Inventors: Toshiharu MATSUSHIMA, Tokyo (JP); Junko NAGASAWA, Tokyo (JP)

(73) Assignee: Japan Display Inc., Tokyo (JP)

(21) Appl. No.: 18/985,906

(22) Filed: Dec. 18, 2024

(30) Foreign Application Priority Data
Dec. 26, 2023 (JP) 2023-219339

(51) Int. Cl. H10K 59/80; H10K 59/122; H10K 59/35

(52) U.S. Cl. CPC H10K 59/879; H10K 59/122; H10K 59/353

(57) ABSTRACT

According to one embodiment, a display device comprises a substrate, a plurality of light emitting elements provided above the substrate, a lower portion surrounding each of the plurality of light emitting elements, an upper portion provided above the lower portion and including a first aperture surrounded by an edge portion projecting from a side surface of the lower portion, and a first lens overlapping at least a part of the first aperture and having a convex shape projecting toward a side opposite to the first aperture.

### CROSS-REFERENCE TO RELATED APPLICATIONS

This application is based upon and claims the benefit of priority from Japanese Patent Application No. 2023-219339, filed Dec. 26, 2023, the entire contents of which are incorporated herein by reference.

### FIELD

Embodiments described herein relate generally to a display device.

### BACKGROUND

In recent display devices, it is requested to render a viewing angle at which a certain contrast can be obtained valuable. For example, in display devices mounted on a vehicle such as an automobile, a viewing angle control is request in which a displayed image is visually recognizable from a side of a passenger seat and, in contrast, a displayed image is visually unrecognizable from a side of a driver seat, for example, at the time of driving.

### BRIEF DESCRIPTION OF THE DRAWINGS

FIG. 1 is a view showing a configuration example of a display device DSP of an embodiment.

FIG. 2 is a schematic plan view showing an example of the layout of subpixels SP1, SP2, and SP3.

FIG. 3 is a plan view showing an example of the layout of apertures A61, A62, and A63 of a partition 6 and lenses ML1 and ML2.

FIG. 4 is a schematic cross-sectional view showing the display device DSP along line A-A′ in FIG. 3.

FIG. 5 is a diagram for explaining an effect of the present embodiment.

FIG. 6 is a plan view showing the display device DSP of the present embodiment that is mounted on a vehicle-mounted device.

FIG. 7 is a schematic cross-sectional view showing another configuration example of the display device DSP along line A-A′ in FIG. 3.

FIG. 8 is a schematic cross-sectional view showing yet another configuration example of the display device DSP along line A-A′ in FIG. 3.

FIG. 9 is a schematic cross-sectional view showing still another configuration example of the display device DSP along line A-A′ in FIG. 3.

FIG. 10 is a schematic cross-sectional view showing still another configuration example of the display device DSP along line A-A′ in FIG. 3.

FIG. 11 is a schematic cross-sectional view showing still another configuration example of the display device DSP along line A-A′ in FIG. 3.

FIG. 12 is a schematic plan view showing an example of the layout of the lenses ML1 and ML2.

FIG. 13 is a schematic plan view showing another example of the layout of the lenses ML1 and ML2.

FIG. 14 is a diagram showing the display device DSP of the present embodiment that is mounted on a vehicle-mounted device.

FIG. 15 is a diagram showing an example of a pixel applicable to the display device DSP shown in FIG. 13.

FIG. 16 is a schematic plan view showing yet another example of the layout of the lenses ML1 and ML2.

FIG. 17 is a diagram showing an example of a pixel applicable to the display device DSP shown in

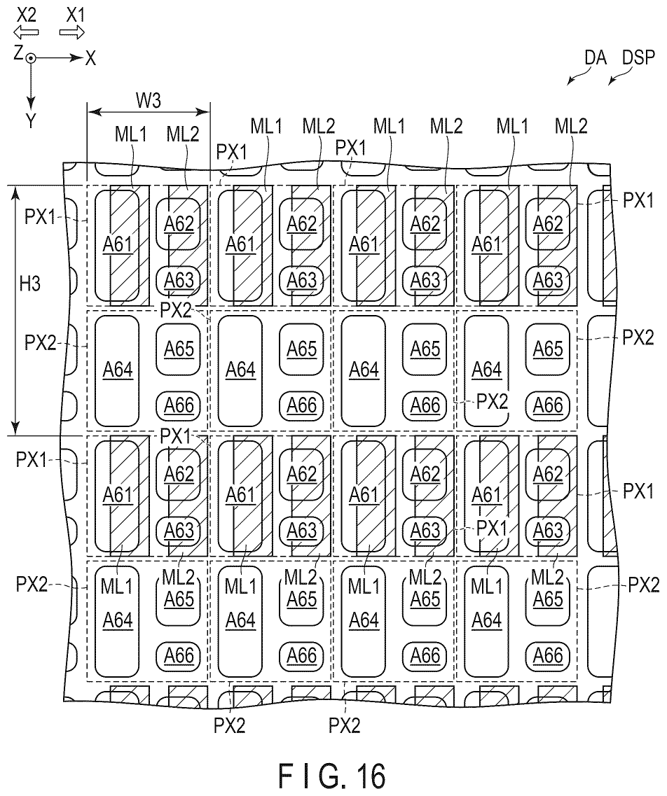

FIG. 16.

FIG. 18 is a schematic plan view showing still another example of the layout of the lenses ML1 and ML2.

FIG. 19 is a schematic plan view showing still another example of the layout of the lenses ML1 and ML2.

FIG. 20 is a schematic plan view showing still another example of the layout of the lenses ML1 and ML2.

FIG. 21 is a schematic plan view showing still another example of the layout of the lenses ML1 and ML2.

FIG. 22 is a plan view showing an example of the layout of the apertures A61, A62, and A63 of the partition 6 and the lenses ML1 and ML2, and a lens ML3.

FIG. 23 is a schematic plan view showing an example of the layout of the lenses ML1, ML2, and ML3.

FIG. 24 is a schematic plan view showing another example of the layout of the lenses ML1, ML2, and ML3.

FIG. 25 is a schematic plan view showing yet another example of the layout of the lenses ML1, ML2, and ML3.

FIG. 26 is a schematic plan view showing still another example of the layout of the lenses ML1, ML2, and ML3.

FIG. 27 is a schematic plan view showing still another example of the layout of the lenses ML1, ML2, and ML3.

### DETAILED DESCRIPTION

In general, according to one embodiment, a display device comprises: a substrate; a plurality of light emitting elements provided above the substrate; a lower portion surrounding each of the plurality of light emitting elements; an upper portion provided above the lower portion and including a first aperture surrounded by an edge portion projecting from a side surface of the lower portion; and a first lens overlapping at least a part of the first aperture and having a convex shape projecting toward a side opposite to the first aperture. The edge portion includes a first aperture edge and a second aperture edge that face each other in a first direction and are parallel to the second direction intersecting the first direction. The plurality of light emitting elements include a first light emitting element overlapping the first aperture. The first aperture has a first center line parallel to the second direction and equidistant from the first aperture edge and the second aperture edge along the first direction. The first lens includes a first lens center line parallel to the second direction. The first lens center line is located between the first center line and the first aperture edge.

Embodiments described herein can provide a display device capable of limiting viewing angles.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as a first direction X, a direction along the Y-axis is referred to as a second direction Y, and a direction along the Z-axis is referred to as a third direction Z. A plan view is defined as appearance when various types of elements are viewed parallel to the third direction Z.

The display device of the present embodiment is an organic electroluminescent display device comprising an organic light emitting diode (OLED) as a display element, and can be mounted on televisions, personal computers, vehicle-mounted devices, tablet terminals, smartphones, mobile phones, and the like.

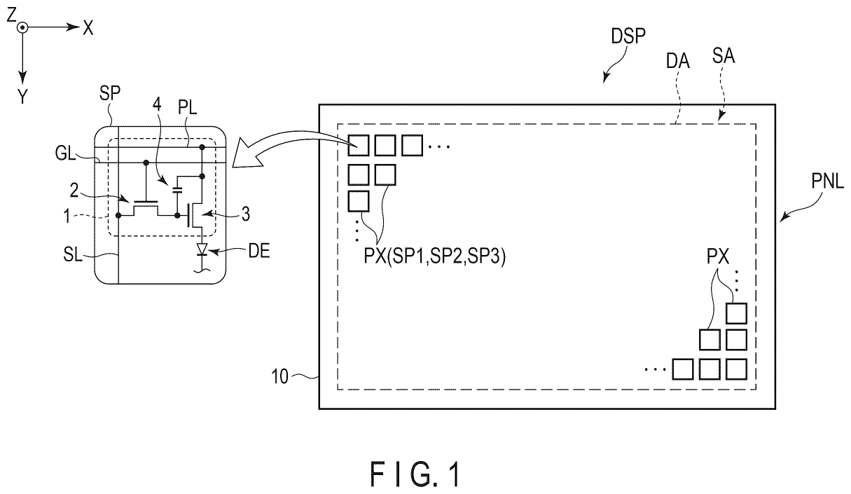

FIG. 1 is a view showing a configuration example of a display device DSP of an embodiment. The display device DSP comprises a display panel PNL comprising a display area DA which displays an image and a surrounding area SA located on an external side relative to the display area DA on an insulating substrate 10. The substrate 10 may be glass or a resinous film having flexibility.

In FIG. 1, the substrate 10 has a rectangular shape having long sides parallel to the first direction X in plan view. It should be noted that the shape of the substrate 10 in a plan view is not limited to this example and may be another shape such as a rectangular shape having long sides parallel to the second direction Y, a square shape, a circular shape, or an elliptic shape.

The display area DA includes a plurality of pixels PX arranged in a matrix in the first direction X and the second direction Y. Each pixel PX includes a plurality of subpixels SP. As an example, each pixel PX includes a subpixel SP1 which exhibits a first color, a subpixel SP2 which exhibits a second color, and a subpixel SP3 which exhibits a third color. The first, second, and third colors are colors different from each other. It should be noted that each pixel PX may include a subpixel SP which exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode or a drain electrode of the pixel switch 2 is connected to a signal line SL. The other is connected to a gate electrode of the drive transistor 3 and the capacitor 4. In the drive transistor 3, one of the source electrode and the drain electrode is connected to a power line PL and the capacitor 4. The other is connected to the anode of the display element DE.

The configuration of the pixel circuit 1 is not limited to the example shown in the figures. For example, the pixel circuit 1 may comprise more thin-film transistors and capacitors.

The display element DE is an organic light emitting diode (OLED) as a light emitting element and thus may be called an organic EL element.

Although not described in detail, a terminal for connecting an IC chip and a flexible printed circuit is provided in the surrounding area SA.

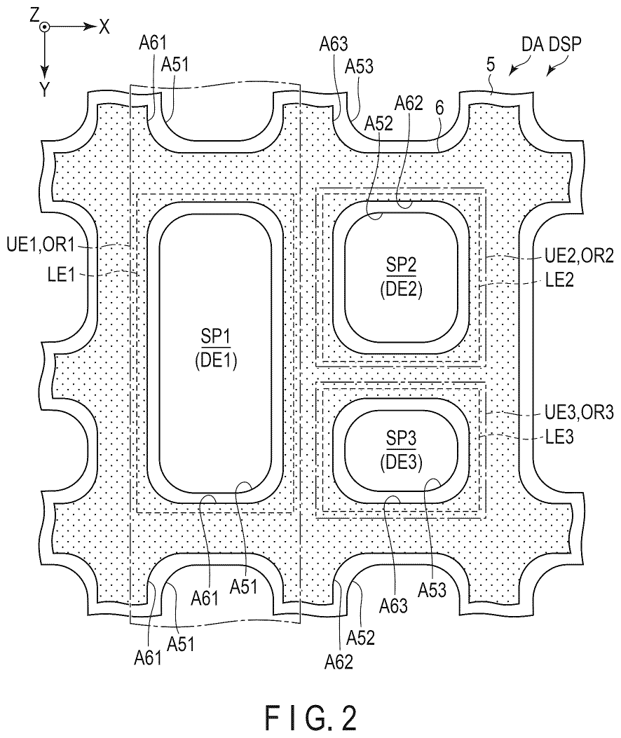

FIG. 2 is a schematic plan view showing an example of the layout of the subpixels SP1, SP2, and SP3. In the example of FIG. 2, the subpixels SP2 and SP3 are arranged in the second direction Y. The subpixels SP1 and SP2 are arranged in the first direction X. The subpixels SP1 and SP3 are arranged in the first direction X.

When the subpixels SP1, SP2, and SP3 are arranged in this layout, for example, a row in which the subpixels SP2 and SP3 are alternately arranged in the second direction Y and a row in which the plurality of subpixels SP1 are repeatedly arranged in the second direction Y are formed in the display area DA. These rows are alternately arranged in the first direction X.

The layout of the subpixels SP1, SP2, and SP3 is not limited to the example of FIG. 2. As another example, the subpixels SP1, SP2, and SP3 in each pixel PX are arranged in an order in the first direction X.

An inorganic insulating layer 5 and a partition 6 are provided in the display area DA. The inorganic insulating layer 5 includes apertures A51, A52, and A53 in the respective subpixels SP1, SP2 and SP3. The inorganic insulating layer 5 having these apertures A51, A52, and A53 may be called a rib.

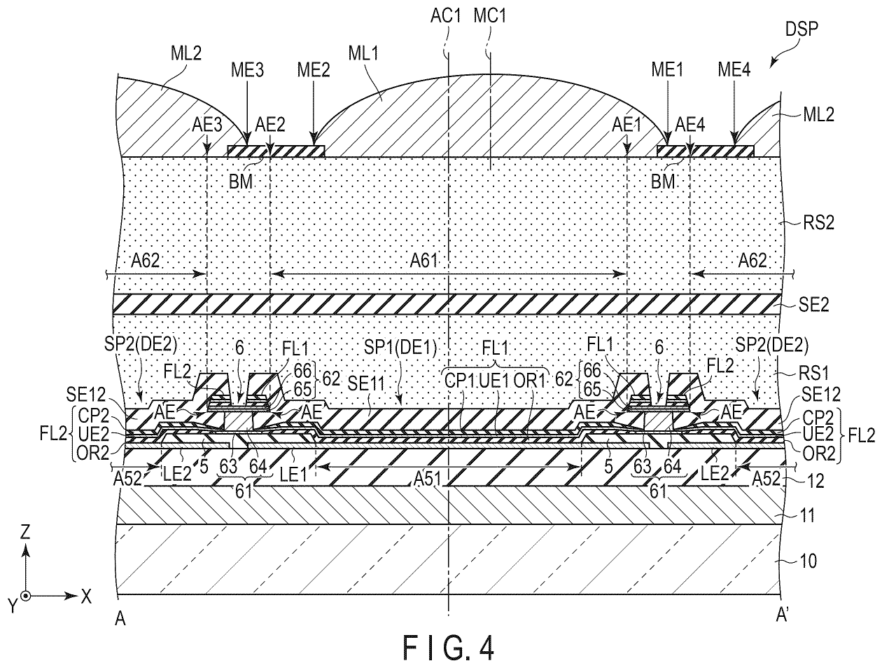

The partition 6 overlaps the inorganic insulating layer 5 as seen in plan view. The partition 6 is formed into a grating shape surrounding the apertures A51, A52, and A53. The partition 6 includes apertures A61, A62, and A63 surrounded by an edge portion of an upper portion of the partition 6, which is to be described later with reference to FIG. 4. The aperture A61 (a first aperture) surrounds the aperture A51 in the subpixel SP1. The aperture A62 (a second aperture) surrounds the aperture A52 in the subpixel SP2. The aperture A63 (a third aperture) surrounds the aperture A53 in the subpixel SP3. In the example of FIG. 2, a corner portion of each of the apertures A51, A52, and A53 and the apertures A61, A62, and A63 has a round shape. The corner portion may have a right angle. Each of the apertures A51, A52, and A53 and the apertures A61, A62, and A63 may have other shapes such as a circular shape and an elliptic shape. The partition 6 is conductive and is electrically connected to a terminal having a common potential, of a plurality of terminals provided in the surrounding area SA shown in FIG. 1.

The subpixels SP1, SP2, and SP3 comprise display elements DE1, DE2, and DE3, respectively, as the display elements DE.

The display element DE1 (a first light emitting element) of the subpixel SP1 comprises a lower electrode LE1, an upper electrode UE1, and an organic layer OR1 that overlap each of the apertures A51 and A61. The display element DE1 comprising the lower electrode LE1, the organic layer OR1, and the upper electrode UE1 is surrounded by the aperture A61 as seen in plan view. A peripheral portion of each of the lower electrode LE1, the organic layer OR1, and the upper electrode UE1 overlaps the inorganic insulating layer 5 as seen in plan view. The organic layer OR1 includes a light emitting layer which emits light in, for example, a green wavelength range.

The display element DE2 (a second light emitting element) of the subpixel SP2 comprises a lower electrode LE2, an upper electrode UE2, and an organic layer OR2 that overlap each of the apertures A52 and A62. The display element DE2 comprising the lower electrode LE2, the organic layer OR2, and the upper electrode UE2 is surrounded by the aperture A62 as seen in plan view. A peripheral portion of each of the lower electrode LE2, the organic layer OR2, and the upper electrode UE2 overlaps the inorganic insulating layer 5 as seen in plan view. The organic layer OR2 includes a light emitting layer which emits light in, for example, a blue wavelength range.

The display element DE3 (a third light emitting element) of the subpixel SP3 comprises a lower electrode LE3, an upper electrode UE3, and an organic layer OR3 that overlap each of the apertures A53 and A63. The display element DE3 comprising the lower electrode LE3, the organic layer OR3, and the upper electrode UE3 is surrounded by the aperture A63 as seen in plan view. A peripheral portion of each of the lower electrode LE3, the organic layer OR3, and the upper electrode UE3 overlaps the inorganic insulating layer 5 as seen in plan view. The organic layer OR3 includes a light emitting layer which emits light in, for example, a red wavelength range.

In the example of FIG. 2, the outer shapes of the lower electrodes LE1, LE2, and LE3 are indicated by dotted lines, and the outer shapes of the organic layers OR1, OR2, and OR3 and the upper electrodes UE1, UE2, and UE3 are indicated by one-dot chain line. It should be noted that the outer shape of each of the lower electrodes, organic layers, and upper electrodes shown in the figure does not necessarily reflect the accurate shape.

For example, the lower electrodes LE1, LE2, and LE3 correspond to the anodes of the display elements. The upper electrodes UE1, UE2, and UE3 correspond to the cathodes of the display elements or a common electrode and are in contact with the partition 6.

In the example of FIG. 2, the area of the aperture A51, the area of the aperture A52, and the area of the aperture A53 are different from each other. The area of the aperture A51 is greater than the area of the aperture A52, and the area of the aperture A52 is greater than the area of the aperture A53. In other words, the area of the lower electrode LE1 exposed from the aperture A51 is greater than the area of the lower electrode LE2 exposed from the aperture A52, and the area of the lower electrode LE2 exposed from the aperture A52 is greater than the area of the lower electrode LE3 exposed from the aperture A53. The magnitude relationship among the apertures A51, A52, and A53 is not limited to the illustrated example.

Similarly, in the example of FIG. 2, the area of the aperture A61, the area of the aperture A62, and the area of the aperture A63 are different from each other. The area of the aperture A61 is greater than the area of the aperture A62, and the area of the aperture A62 is greater than the area of the aperture A63. The magnitude relationship among the apertures A61, A62, and A63 is not limited to the illustrated example.

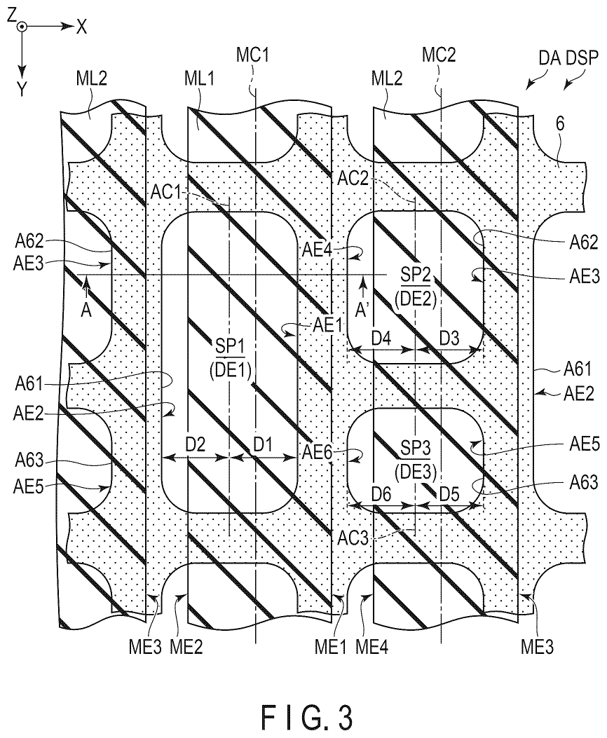

FIG. 3 is a plan view showing an example of the layout of the apertures A61, A62, and A63 of the partition 6 and the lenses ML1 and ML2. It should be noted that the illustration of the lower electrode, organic layer, upper electrode, etc., constituting the display element of each subpixel is omitted in FIG. 3. In the aperture A61, the edge portion of the partition 6 includes an aperture edge AE1 (a first aperture edge) and an aperture edge AE2 (a second aperture edge). The aperture A61 includes a center line AC1 (a first center line). The aperture edges AE1 and AE2 and the center line AC1 are parallel to the second direction Y. The aperture edges AE1 and AE2 face each other in the first direction X. The center line AC1 is located equidistantly from the aperture edges AE1 and AE2 along the first direction X. In the example of FIG. 3, a distance D1, which is along the first direction X between the aperture edge AE1 and the center line AC1, is equivalent to a distance D2, which is along the first direction X between the aperture edge AE2 and the center line AC1 (D1=D2).

In the aperture A62, the edge portion of the partition 6 includes an aperture edge AE3 (a third aperture edge) and an aperture edge AE4 (a fourth aperture edge). The aperture A62 includes a center line AC2 (a second center line). The aperture edges AE3 and AE4 and the center line AC2 are parallel to the second direction Y. The aperture edges AE3 and AE4 face each other in the first direction X. The center line AC2 is located equidistantly from the aperture edges AE3 and AE4 along the first direction X. In the example of FIG. 3, a distance D3, which is along the first direction X between the aperture edge AE3 and the center line AC2, is equivalent to a distance D4, which is along the first direction X between the aperture edge AE4 and the center line AC2 (D3=D4).

In the aperture A63, the edge portion of the partition 6 includes an aperture edge AE5 (a fifth aperture edge) and an aperture edge AE6 (a sixth aperture edge). The aperture A63 includes a center line AC3 (a third center line). The aperture edges AE5 and AE6 and the center line AC3 are parallel to the second direction Y. The aperture edges AE5 and AE6 face each other in the first direction X. The center line AC3 is located equidistantly from the aperture edges AE5 and AE6 along the first direction X. In the example of FIG. 3, a distance D5, which is along the first direction X between the aperture edge AE5 and the center line AC3, is equivalent to a distance D6, which is along the first direction X between the aperture edge AE6 and the center line AC3 (D5=D6).

The display device DSP further comprises a lens ML1 (a first lens) and a lens ML2 (a second lens). In the example of FIG. 3, the lenses ML1 and ML2 extend in the second direction Y and face a plurality of subpixels arranged in the second direction Y.

The lens ML1 overlaps a part of the aperture A61. The lens ML1 includes lens edges ME1 and ME2 and a lens center line MC1 (a first lens center line). The lens edges ME1 and ME2, and the lens center line MC1 are parallel to the second direction Y. In the illustrated example, the lens edge ME1 overlaps the partition 6 in plan view and is located between the aperture edge AE1 and the aperture edge AE4 and between the aperture edge AE1 and the aperture edge AE6 in the first direction X. Further, in plan view, the lens edge ME2 intersects the partition 6, overlaps the aperture A61, and is located between the aperture edge AE2 and the center line AC1 in the first direction X. The lens ML1 covers not the aperture edge AE2 but the aperture edge AE1. The lens center line MC1 is located between the center line AC1 and the aperture edge AE1 in plan view.

In the illustrated example, the lens ML1 does not completely cover the aperture A61 in the first direction X. However, unlike this example, the lens ML1 may completely cover the aperture A61.

The lens ML2 continuously overlaps a part of each of the apertures A62 and A63. The lens ML2 includes lens edges ME3 and ME4 and a lens center MC2 (a second lens center line). The lens edges ME3 and ME4, and the lens center MC2 are parallel to the second direction Y. In the illustrated example, in plan view, the lens edge ME3 overlaps the partition 6 and is located between the aperture edge AE2 and the aperture edge AE3 and between the aperture edge AE2 and the aperture edge AE5 in the first direction X. Further, in plan view, the lens edge ME4 intersects the partition 6, overlaps the apertures A62 and A63, and is located between the aperture edge AE4 and the center line AC2 and between the aperture edge AE6 and the center line AC3 in the first direction X. The lens ML2 continuously covers the aperture edges AE3 and AE5. The lens ML2 does not cover the aperture edges AE4 and AE6. The lens center MC2 is located between the center line AC2 and the aperture edge AE3 and between the center line AC3 and the aperture edge AE5.

In the illustrated example, the lens ML2 does not completely cover the apertures A62 and A63 in the first direction X. However, unlike this example, the lens ML2 may completely cover the apertures A62 and A63.

In this specification, the term “lens center line” signifies a line connecting a plurality of principal points of the lens. A principal point is a point at which the main surface of the lens and optical axis intersect each other. The main surface includes an intersection of light beam before being made incident and light beam after being made incident in a case of making light beam parallel to an optical axis on the lens and intersects the optical axis.

FIG. 4 is a schematic cross-sectional view showing the display device DSP along line A-A′ in FIG. 3. A circuit layer 11 is provided on the substrate 10. The circuit layer 11 includes various circuits such as the pixel circuit 1 shown in FIG. 1 and various lines such as the scanning line GL, the signal line SL, and a power line PL. The circuit layer 11 is covered with an insulating layer 12. The insulating layer 12 is an organic insulating layer which planarizes the uneven parts formed by the circuit layer 11.

The lower electrodes LE1 and LE2 are provided on the insulating layer 12 and are spaced apart from each other. The inorganic insulating layer 5 is provided on the insulating layer 12 and the lower electrodes LE1 and LE2. The aperture A51 of the inorganic insulating layer 5 overlaps the lower electrode LE1. The aperture A52 of the inorganic insulating layer 5 overlaps the lower electrode LE2. The peripheral portion of each of the lower electrodes LE1 and LE2 is covered with the inorganic insulating layer 5. In lower electrodes that are adjacent to each other among the lower electrodes LE1 and LE2, the insulating layer 12 is covered with the inorganic insulating layer 5. The lower electrodes LE1 and LE2 are connected to the pixel circuit 1 of each of the subpixels SP1 and SP2 through a contact hole provided in the insulating layer 12. The illustration of the contact hole of the insulating layer 12 is omitted in FIG. 4.

The partition 6 includes a conductive lower portion 61 provided on the inorganic insulating layer 5 and an upper portion 62 provided on the lower portion 61. The lower portion 61 surrounds each of the display elements DE1 and DE2 in plan view. The upper portion 62 includes an edge portion AE surrounding each of the apertures A61 and A62 in plan view. The edge portion AE protrudes relative to the side surfaces of the lower portion 61. This shape of the partition 6 is called an overhang shape.

In the illustrated example, the lower portion 61 includes a first conductive layer 63 provided on the inorganic insulating layer 5 and a second conductive layer 64 provided on the first conductive layer 63. For example, the first conductive layer 63 is thinner than the second conductive layer 64. Further, in the illustrated example, the both end portions of the first conductive layer 63 project relative to the respective side surfaces of the second conductive layer 64.

The upper portion 62 includes a thin film 65 provided on the second conductive layer 64 and a thin film 66 provided on the thin film 65. The both end portions of the thin film 65 and thin film 66 project relative to the respective side surfaces of the second conductive layer 64. In the illustrated example, the end portions of the thin film 65 surround the apertures A61 and A62. The edge portion AE corresponds to, for example, the end portions of the thin film 65.

The organic layer OR1 is in contact with the lower electrode LE1 through the aperture A51 and covers the lower electrode LE1 exposed from the aperture A51. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture A52 and covers the lower electrode LE2 exposed from the aperture A52. The peripheral portion of the organic layer OR2 is located on the inorganic insulating layer 5. The upper electrode UE2 covers the organic layer OR2 and is in contact with the lower portion 61.

In the example of FIG. 4, the subpixel SP1 includes a cap layer CP1 and a first sealing layer SE11. The subpixel SP2 includes a cap layer CP2 and a first sealing layer SE12. The cap layers CP1 and CP2 function as optical adjustment layers which improve the extraction efficiency of light emitted from the respective organic layers OR1 and OR2. It should be noted that the cap layers CP1 and CP2 may be omitted. The cap layer CP1 is provided on the upper electrode UE1. The cap layer CP2 is provided on the upper electrode UE2.

The first sealing layer SE11 is provided on the cap layer CP1, is in contact with the partition 6, and continuously covers each member of the subpixel SP1. The first sealing layer SE12 is provided on the cap layer CP2, is in contact with the partition 6, and continuously covers each member of the subpixel SP2.

In the example of FIG. 4, portions of the organic layer OR1, the upper electrode UE1, and the cap layer CP1 are located on the partition 6 around the subpixel SP1. These portions are spaced apart from portions located in the aperture A51 (the portions constituting the display element DE1) of the organic layer OR1, the upper electrode UE1, and the cap layer CP1.

Similarly, portions of the organic layer OR2, the upper electrode UE2, and the cap layer CP2 are located on the partition 6 around the subpixel SP2. These portions are spaced apart from the portions located in the aperture A52 (the portions constituting the display element DE2) of the organic layer OR2, the upper electrode UE2, and the cap layer CP2.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2.

The end portions of each of the sealing layers SE11 and SE12 and the end portions of each of the stacked films FL1 and FL2 are located on the partition 6. In the example of FIG. 4, the stacked film FL1 located on the partition 6 and the first sealing layer SE11 between the subpixels SP1 and SP2 are spaced apart from the stacked film FL2 located on this partition 6 and the first sealing layer SE12.

The partition 6 and the first sealing layers SE11 and SE12 are covered with an organic insulating layer RS1 (a first organic insulating layer). The organic insulating layer RS1 is covered with a second sealing layer SE2. The second sealing layer SE2 is covered with an organic insulating layer RS2 (a second organic insulating layer). In the illustrated example, the organic insulating layer RS2 is thicker than the organic insulating layer RS1.

The lenses ML1 and ML2 are provided on the organic insulating layer RS2. The lenses ML1 and ML2 have convex shapes projecting toward a side opposite to the apertures A61 and A62 in the third direction Z. The lens ML1 overlaps the lower electrode LE1, the stacked film FL1, and the first sealing layer SE11 in the third direction Z. The lens ML2 overlaps the lower electrode LE2, the stacked film FL2, and the first sealing layer SE12 in the third direction Z. As an example, the lenses ML1 and ML2 are covered with an air layer. As another example, the lenses ML1 and ML2 are covered with a material that has the refractive index smaller than that of each of the lenses ML1 and ML2.

A focus of each of the lenses ML1 and ML2 is preferably coincident with the position of the light emitting layers included in the organic layers OR1 and OR2. The position of the focus of each of the lenses ML1 and ML2 can be coincident with the position of the light emitting layers, for example, by varying the thicknesses of the organic insulating layers RS1 and RS2.

A cover member such as a polarizer and a cover glass may further be provided above the lenses ML1 and ML2.

The display device DSP further comprises a light-shielding layer BM provided on the organic insulating layer RS2. The light-shielding layer BM covers a portion between the lenses ML1 and ML2. In the illustrated example, the both end portions of the light-shielding layer BM are covered with the lenses ML1 and ML2. The light-shielding layer BM needs to cover a portion that is at least not covered with lenses of apertures of the partition 6.

Each of the inorganic insulating layer 5, the first sealing layers SE11 and SE12, and the second sealing layer SE2 is formed of, for example, an inorganic insulating material such as silicon nitride (SiNx), silicon oxide (Siox), silicon oxynitride (SiON), or aluminum oxide (Al₂O₃). Each of the organic insulating layers RS1 and RS2 is formed of, for example, a resinous material (an organic insulating material) such as epoxy resin or acrylic resin.

The lower portion 61 of the partition 6 is formed of a conductive material and is electrically connected to the upper electrodes UE1 and UE2. The first conductive layer 63 is formed of, for example, titanium-based material such as titanium and titanium compound. The second conductive layer 64 is formed of a material that is different from each of the first conductive layer 63 and the upper portion 62. For example, the second conductive layer 64 is formed of aluminum-based material such as aluminum and aluminum compound.

The upper portion 62 of the partition 6 is formed of, for example, a conductive material. However, the upper portion 62 may be formed of an insulating material. The thin film 65 is, formed of, for example, titanium-based material such as titanium and titanium compound. The thin film 66 is formed of, for example, oxide conductive material such as indium tin oxide (ITO).

Each of the lower electrodes LE1 and LE2 is a multilayer body including a transparent layer formed of an oxide conductive material such as indium tin oxide (ITO) and a reflective layer formed of a metal material such as silver. For example, each of the lower electrodes LE1 and LE2 is a multilayer body including the reflective layer between a pair of transparent layers. The transparent layer of the lower layer functions as a close-contact layer in close contact with the insulating layer 12.

As an example, the organic layer OR1 includes a light emitting layer formed of a material emitting light in a green wavelength, and the organic layer OR2 includes a light emitting layer formed of a material emitting light in a blue wavelength. As another example, the organic layer OR1 includes a light emitting layer formed of a material emitting light in a blue wavelength, and the organic layer OR2 includes a light emitting layer formed of a material emitting light in a green wavelength. Each of the organic layers OR1 and OR2 includes a plurality of functional layers such as a hole injection layer, a hole transport layer, an electron blocking layer, a hole blocking layer, an electron transport layer, and an electron injection layer.

The upper electrodes UE1 and UE2 are formed of, for example, a metal material such as an alloy of magnesium and silver (MgAg). Each of the cap layers CP1 and CP2 is a multilayer body consisting of a plurality of thin films. All of the plurality of thin films are transparent and have refractive indexes different from each other.

The lenses ML1 and ML2 are formed of, for example, a transparent resinous material such as epoxy resin, acrylic resin, and polyimide resin.

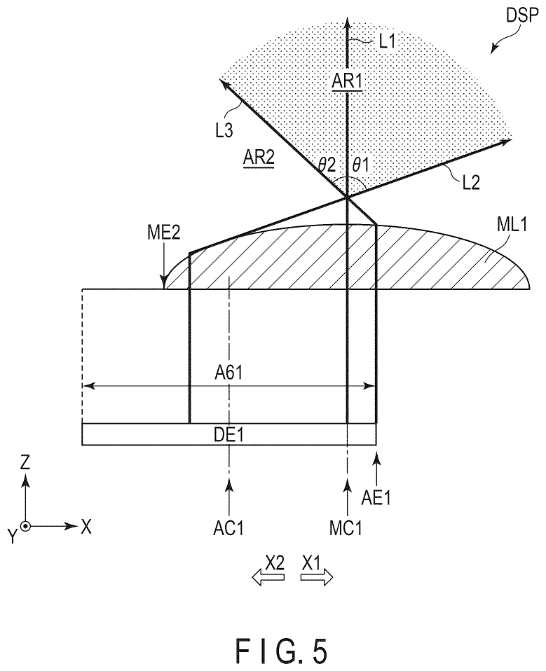

Next, an effect of the present embodiment will be described with reference to FIG. 5. FIG. 5 is a diagram for explaining the effect of the present embodiment. A direction toward the lens center line MC1 from the center line AC1 along the first direction X is hereinafter referred to as a direction X1. A direction toward the center line AC1 from the lens center line MC1 along the first direction X is hereinafter referred to as a direction X2.

Light beam L1, which is emitted from the display element DE1 along the third direction Z and passes through the lens center line MC1, travels in the lens ML1 substantially without being refracted. In the illustrated example, the light beam L1 travels along the third direction Z.

In addition, light beam L2, which is emitted from the display element DE1 along the third direction Z and is made incident on the lens ML1 provided in the vicinity of the lens edge ME2, is refracted at the interface between the lens ML1 and air. The light beam L2, which has been refracted, travels along a direction tilted by angle θ1 from the third direction Z to the direction X1.

In addition, light beam L3, which is emitted from the display element DE1 in the vicinity of the aperture edge AE1 along the third direction Z and is made incident on the lens ML1, is refracted at the interface between the lens ML1 and air. The light beam L3, which has been refracted, travels along a direction tilted by angle θ2 from the third direction Z to the direction X2.

In the illustrated example, an area combining the area between the light beam L1 and the light beam L2 and the area between the light beam L1 and the light beam L3 is defined as an area AR1, and the other areas are defined as an area AR2. In this configuration, a user in the area AR1 can visually recognize an image displayed on the display device DSP. In contrast, a user in the area AR2 can hardly recognize the image visually.

When the lens center line MC1 and the center line AC1 coincide with each other, the angle θ1 and the angle θ2 are equivalent to each other (θ1=θ2). In contrast, as in the present embodiment, when the lens center line MC1 is close to the aperture edge AE1, the angle θ2 decreases to be smaller than the angle θ1 (θ1 >θ2). Therefore, of the area AR1, the area close to a side of the direction X2 with respect to the lens center line MC1 is narrower than the area close to a side of the direction X1 with respect to the lens center line MC1. Therefore, the viewing angle in the side of the direction X2 can be limited.

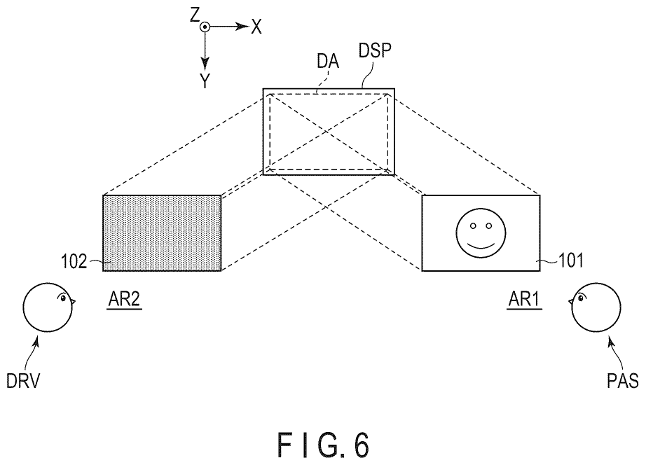

Next, a case where the display device DSP of the present embodiment will be mounted on a vehicle such as an automobile will be described. FIG. 6 is a plan view showing the display device DSP of the present embodiment that is mounted on a vehicle-mounted device. As an example, a case in which the display device DSP is located between a driver seat and a passenger seat will be described. The display device DSP may be located in front of the passenger seat.

For example, at the time of driving, it is required that an image displayed on the display device DSP is hardly visually recognizable from a side of a driver seat and, in contrast, this image is visually recognizable from a passenger seat. In that case, the display device DSP is provided such that a passenger PAS sitting on a passenger seat is included in the area AR1 and a driver DRV is included in the area AR2. Thus, the passenger PAS sitting on the passenger seat in the area AR1 can visually recognize a screen 101, on which an image is displayed in the display area DA. In contrast, the visual recognition of the displayed image is restricted for the driver DRV in the area AR2. The driver DRV can visually recognize a screen 102 on which a darker image, compared to the one which can be seen from the side of the passenger seat, or no image is displayed. In this manner, the visually recognition of an image by the driver DRV can be restricted by limiting the viewing angle of the side of the driver seat.

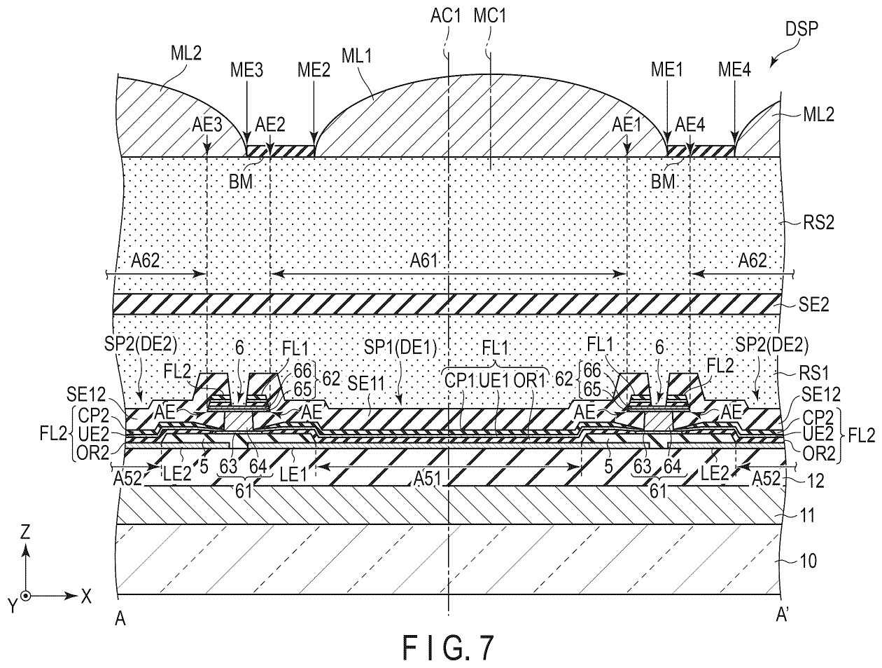

FIG. 7 is a schematic cross-sectional view showing another configuration example of the display device DSP along line A-A′ in FIG. 3. In the example shown in FIG. 7, the end portion of the light-shielding layer BM is in contact with each of the lens edges ME1 to ME4.

The display device DSP shown in FIG. 7 can exhibit the same effects as those achieved by the display device DSP shown in FIG. 4.

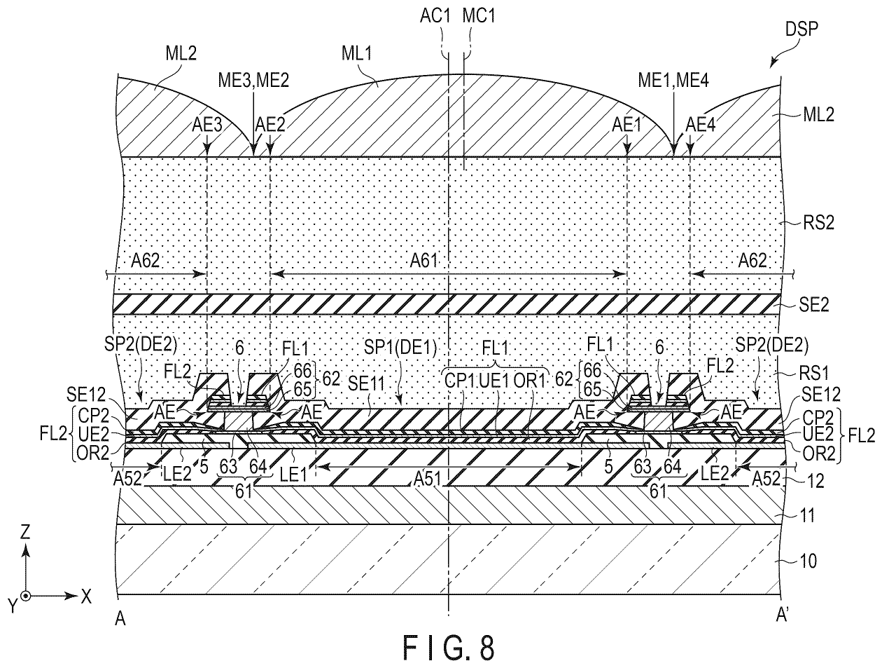

FIG. 8 is a schematic cross-sectional view showing yet another configuration example of the display device DSP along line A-A′ in FIG. 3. The display device DSP shown in FIG. 8 is different from the display device DSP shown in FIG. 4 in not comprising the light-shielding layer BM shown in FIG. 4 and the lenses ML1 and ML2 being in contact with each other.

The lenses ML1 and ML2 are in contact with each other. More specifically, the lens edge ME1 of the lens ML1 is in contact with the lens edge ME4 of the lens ML2, and the lens edge ME2 of the lens ML1 is in contact with the lens edge ME3 of the lens ML2. In other words, the aperture of the partition 6 is completely covered with the lenses. In the example of FIG. 8, on the upper surface of the organic insulating layer RS2, the lens edges ME1 and ME4 are in contact with each other, and the lens edges ME2 and ME3 are in contact with each other. These contacts may be achieved above the organic insulating layer RS2, instead of on the upper surface of the organic insulating layer RS2.

In the display device DSP shown in FIG. 8, the aperture of the partition 6 is completely covered with the lenses. Therefore, the light-shielding layer BM shown in FIG. 4 is unnecessary. Thus, the brightness of the display device DSP can be increased.

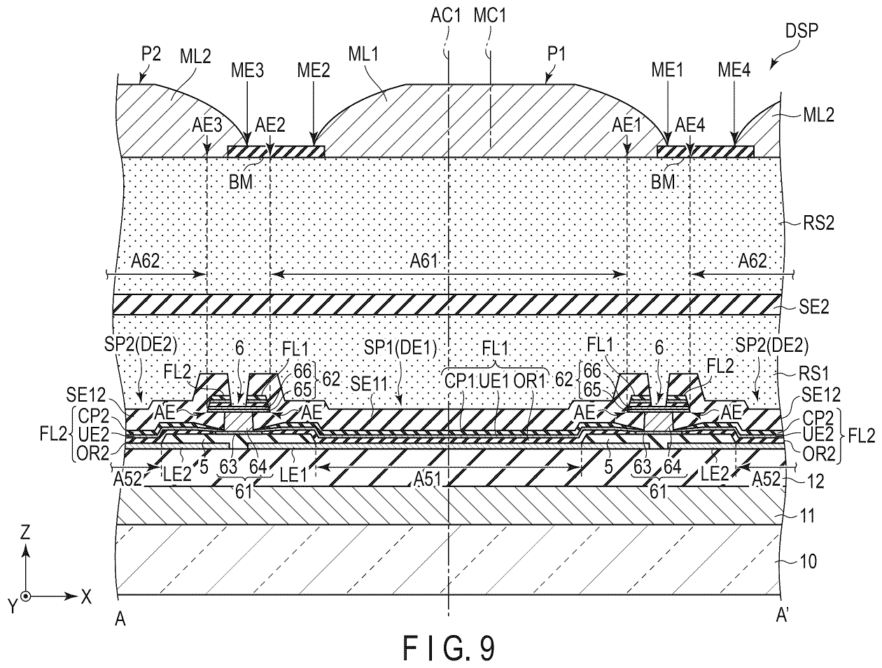

FIG. 9 is a schematic cross-sectional view showing still another configuration example of the display device DSP along line A-A′ in FIG. 3. The display device DSP shown in FIG. 9 is different from the display device DSP shown in FIG. 4 in a point that the cross-sectional shapes of the lenses ML1 and ML2 are different from each other.

The lens ML1 has a flat surface P1 on its apex portion. The lens ML2 has a flat surface P2 on its apex portion. In the example shown in FIG. 9, the surfaces P1 and P2 are parallel to the first direction X and the second direction Y. The surfaces P1 and P2 may be inclined to a surface defined by the first direction X and the second direction Y.

The display device DSP shown in FIG. 9 can exhibit the same effects as those achieved by the display device DSP shown in FIG. 4.

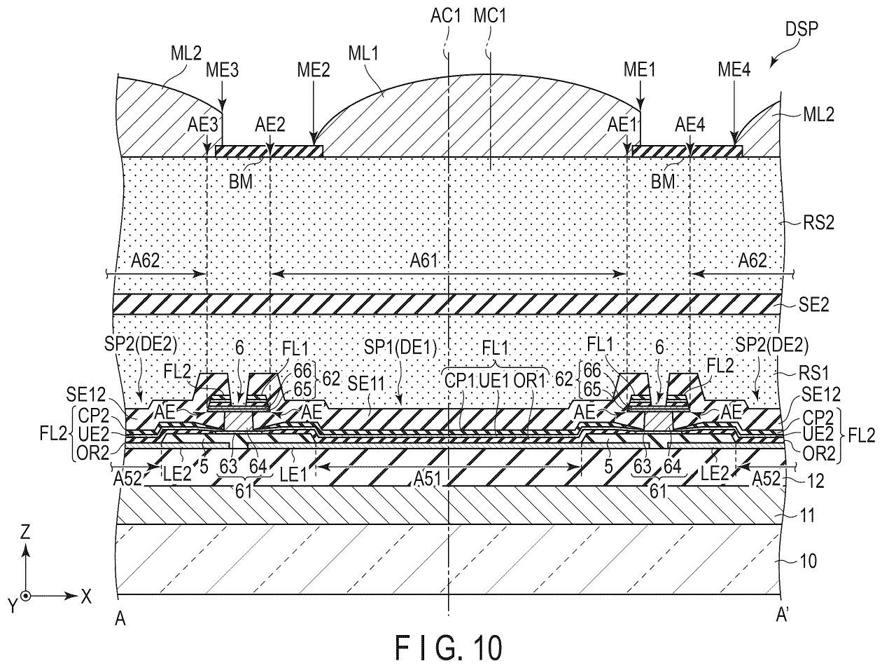

FIG. 10 is a schematic cross-sectional view showing still another configuration example of the display device DSP along line A-A′ in FIG. 3. The display device DSP shown in FIG. 10 is different from the display device DSP shown in FIG. 4 in a point that the cross-sectional shapes of the lenses ML1 and ML2 are different from each other.

The lens ML1 has a cross-section asymmetric with respect to the lens center line MC1. In the example of FIG. 10, the lens edge ME1 is formed as a plane surface parallel to the second direction Y and the third direction Z. Similarly to the lens ML1, in the lens ML2, the lens edge ME3 is formed as a plane surface parallel to the second direction Y and the third direction Z.

The display device DSP shown in FIG. 10 can exhibit the same effects as those achieved by the display device DSP shown in FIG. 4.

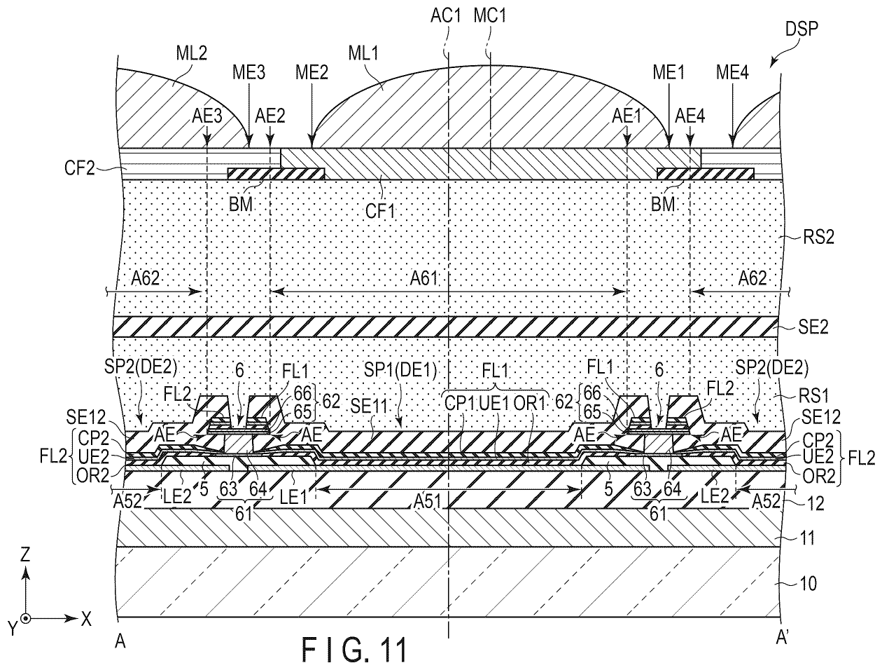

FIG. 11 is a schematic cross-sectional view showing still another configuration example of the display device DSP along line A-A′ in FIG. 3. The display device DSP shown in FIG. 11 is different from the display device DSP shown in FIG. 4 in comprising a color filter.

The display device DSP further comprises color filters CF1 and CF2. The color filter CF1 is provided between the organic insulating layer RS2 and the lens ML1 in the third direction Z. The color filter CF1 is provided immediately above the display element DE1. As an example, the color filter CF1 is formed of a green-colored resin material.

The color filter CF2 is provided between the organic insulating layer RS2 and the lens ML2 in the third direction Z. The color filter CF2 is provided immediately above the display element DE2. As an example, the color filter CF2 is formed of a blue-colored resin material.

The light-shielding layer BM overlaps a peripheral portion of each of the color filters CF1 and CF2. In the illustrated example, the light-shielding layer BM covers the lens edges ME1 to ME4 in plan view.

Though not illustrated, the display device DSP comprises a color filter provided immediately above the display element DE3 shown in FIG. 2. As an example, this color filter is formed of a red-colored resin material.

In the display device DSP shown in FIG. 11, for example, green light emitted from the display element DE1 passes through the color filter CF1. In contrast, blue light emitted from the display element DE2 is absorbed by the color filter CF1. Thus, color mixture in light can be suppressed. This results in suppressing degradation in display quality.

The display device DSP shown in FIG. 11 can exhibit the same effects as those achieved by the display device DSP shown in FIG. 4.

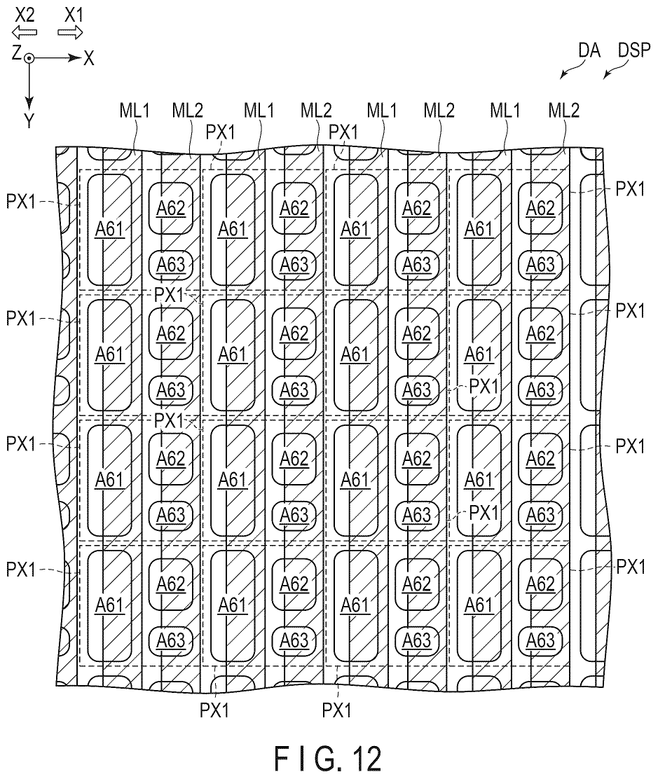

FIG. 12 is a schematic plan view showing an example of the layout of the lenses ML1 and ML2. The display device DSP further comprises a plurality of pixels PX1 (first pixels) in the display area DA. Each of the plurality of pixels PX1 includes the apertures A61, A62, and A63. In the illustrated example, the plurality of pixels PX1 are repeatedly arranged in the second direction Y. In addition, the rows of the plurality of pixels PX1 arranged in the second direction Y are repeatedly arranged in the first direction X.

The lenses ML1 and ML2 continuously overlap in the third direction Z the plurality of pixels PX1 arranged along the second direction Y. More specifically, the lenses ML1 continuously overlap in the third direction Z the plurality of apertures A61 arranged along the second direction Y. Further, the lenses ML2 continuously overlap in the third direction Z the apertures A62 and the apertures A63 alternately arranged along the second direction Y. The lenses ML1 and ML2 may be interrupted per pixel in the second direction Y.

The display device DSP shown in FIG. 12 can exhibit the same effects as those achieved by the display device DSP shown in FIG. 4.

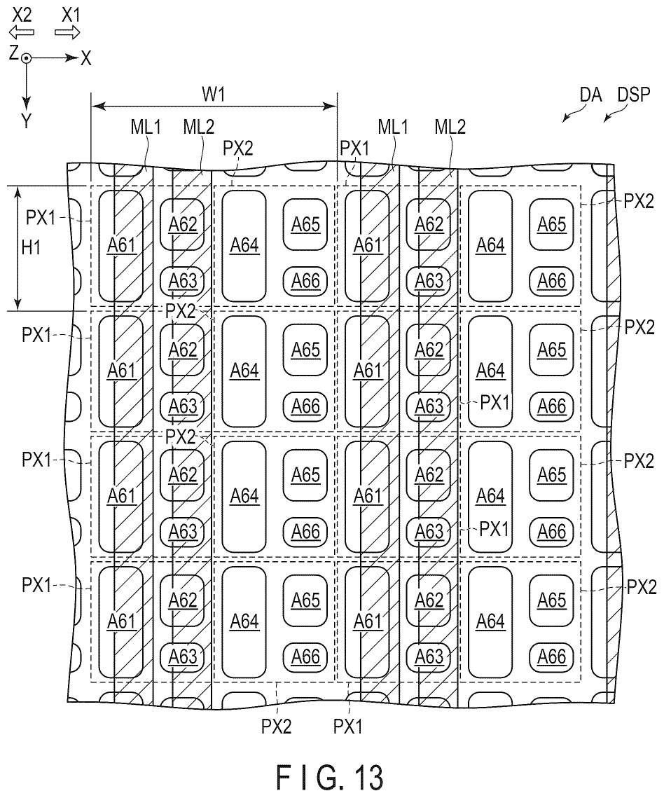

FIG. 13 is a schematic plan view showing another example of the layout of the lenses ML1 and ML2. The display device DSP further comprises a plurality of pixels PX2 (second pixels) in the display area DA. Each of the plurality of pixels PX2 includes apertures A64, A65, and A66 that are surrounded by the edge portion AE of the upper portion 62 of the partition 6 shown in FIG. 4. Each of the apertures A64, A65, and A66 overlaps a plurality of display elements (not shown) included in the pixel PX2. The pixel PX2 has the configuration equivalent to that of the pixel PX1 and thus the detailed explanation thereof will not be provided. The pixel PX2 comprises the same display elements as the display elements DE1, DE2, and DE3 included in the pixel PX1.

In the example shown in FIG. 13, the aperture A64 (a fourth aperture) is adjacent to each of the apertures A62, A63, A65, and A66 in the first direction X. In addition, the aperture A65 (a fifth aperture) is adjacent to the apertures A61 and A64 in the first direction X and is adjacent to the aperture A66 in the second direction Y. In addition, the aperture A66 (a sixth aperture) is adjacent to the apertures A61 and A64 in the first direction X and is adjacent to the aperture A65 in the second direction Y.

Each of the apertures A64, A65, and A66 does not overlap any of the lenses and does not overlap any of the lenses ML1 and ML2, which overlap the pixel PX1, in the third direction Z. Therefore, light emitted from display elements overlapping any of the apertures A64, A65, and A66 is not subjected to limitation on the viewing angle.

The plurality of pixels PX1 are repeatedly arranged in the second direction Y. The plurality of pixels PX2 are repeatedly arranged in the second direction Y. The row of the plurality of pixels PX1 arranged in the second direction Y and the row of the plurality of pixels PX2 arranged in the second direction Y are alternately arranged in the first direction X. As an example, the number of the pixels PX1 arranged in the display area DA is almost equivalent to the number of the pixels PX2 arranged in the display area DA.

With respect to the pixels PX1 and PX2 that are alternately arranged in the first direction X, the relationship between a length W1, which is along the first direction X combining the lengths of the adjacent pixels PX1 and PX2, and a length H1, which is the length of one pixel PX1 along the second direction Y of the pixels PX1 arranged in the second direction Y, is represented as follows. In the illustrated example, the pixels PX1 and PX2 have the same length along the first direction X. Further, the pixel PX1 has the same length along the first direction X and the second direction Y. That is, the length W1 is approximately twice the length H1 (W1=2×H1).

As described above, in the pixel PX1, the lens ML1 overlaps the aperture A61, and the lens ML2 overlaps the apertures A62 and A63. In the pixel PX2, the lenses ML1 and ML2 do not overlap each of the apertures A64, A65, and A66. That is, the lenses ML1 and ML2 are arranged in the first direction X by every two pixels. The lenses may be arranged by every n-pixels (n is an integer of two or more). That is, the length W1 is approximately n-times of the length H1 (W1=n×H1).

When the display device DSP shown in FIG. 13 has a state where the plurality of pixels PX1 are tuned on and the plurality of pixels PX2 are turned off (hereinafter, this state is referred to as a first mode), the viewing angle of the display device DSP is limited. In contrast, in a case where the plurality of pixels PX1 are tuned off and the plurality of pixels PX2 are turned on or where both of the plurality of pixels PX1 and PX2 are turned on (hereinafter, this state is referred to as a second mode), the viewing angle of the display device DSP is wider compared to that in the first mode. Therefore, the viewing angle of the display device DSP can be controlled by switching the first mode and the second mode according to the usage of the display device DSP.

The number of the pixels PX1 in the display device DSP shown in FIG. 13 is approximately the half of the number of the pixels PX1 in the display device DSP shown in FIG. 12. Therefore, the resolution of an image which the display device DSP in FIG. 13 displays in the first mode is approximately the half of the resolution of an image which the display device DSP in FIG. 12 displays. Here, the resolution signifies the number of pixels contributing to displaying per unit area. In the display device DSP shown in FIG. 13, the number of the pixels PX2 is almost equivalent to the number of the pixels PX1. Therefore, when the pixels PX2 are turned on without turning on the pixels PX1, the resolution of an image which the display device DSP in FIG. 13 displays is approximately the half of the resolution of an image which the display device DSP in FIG. 12 displays. That is, the resolution of the image in the above case is almost equivalent to the resolution of the image displayed in the first mode.

In contrast, when both of the pixels PX1 and PX2 are turned on, light of both of the pixels PX1 and PX2 can be visually recognized from the side of the direction X1, and light of the pixels PX2 alone can be visually recognized from the side of the direction X2. Therefore, when both of the pixels PX1 and PX2 are turned on, the resolution in a case where an image which the display device DSP in FIG. 13 displays is seen from the side of the direction X1 is almost equivalent to the resolution of an image which the display device DSP in FIG. 12 displays. That is, the resolution of the image in the above case is approximately twice the resolution of the image displayed in the first mode. Further, when both of the pixels PX1 and PX2 are turned on, the resolution in a case where an image which the display device DSP in FIG. 13 displays is seen from the side of the direction X2 is approximately the half of the resolution of an image which the display device DSP in FIG. 12 displays. That is, the resolution of the image in the above case is almost equivalent to the resolution of the image displayed in the first mode.

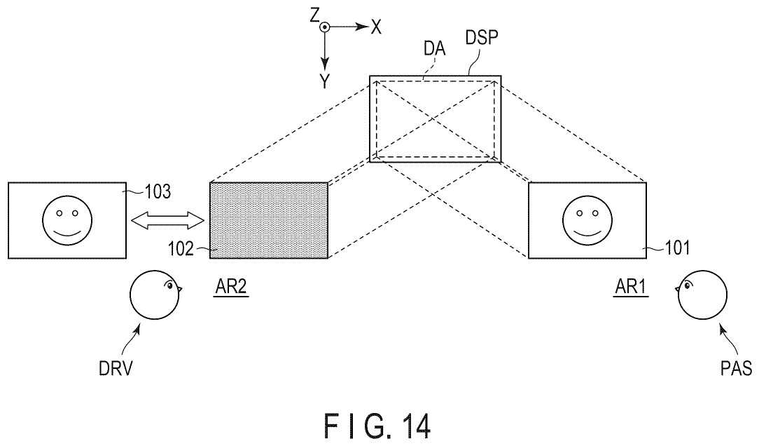

Next, a case where the display device DSP shown in FIG. 13 will be mounted on a vehicle such as an automobile will be described. FIG. 14 is a diagram showing the display device DSP of the present embodiment that is mounted on a vehicle-mounted device. As an example, a case in which the display device DSP is located between a driver seat and a passenger seat will be described. The display device DSP may be located in front of the passenger seat.

Similarly to the case described with reference to FIG. 6, when an image is displayed in the first mode, the passenger PAS sitting on the passenger seat in the area AR1 can visually recognize the screen 101, on which an image is displayed in the display area DA. In contrast, the visual recognition of the displayed image is restricted for the driver DRV in the area AR2. The driver DRV can visually recognize a screen 102 on which a darker image, compared to the one which can be seen from the side of the passenger seat, or no image is displayed.

When an image is displayed in the second mode, the passenger PAS in the passenger seat can visually recognize the screen 101, on which an image is displayed in the display area DA. In contrast, the driver DRV can visually recognize a screen 103 on which the same image as the image visually recognized by the passenger PAS in the passenger seat is displayed.

At the time of driving, an image is displayed in the first mode when the following case is required: an image displayed on the display device DSP is hardly visually recognizable from the side of the driver seat and, in contrast, this image is visually recognizable from a passenger seat. Thus, the visual recognition of an image is limited from the side of the driver seat. In contrast, the image is sufficiently visually recognizable from the side of the passenger seat. In contrast, an image is displayed in the second mode when the following case is required: an image is visually recognizable from both the side of the driver seat and the side of the passenger seat while engine is in off state. Thus, an image is sufficiently visually recognized from both the side of the driver seat and the side of the passenger seat. By switching the first mode and the second mode in this manner, the viewing angle is controlled. Thus, the visibility of an image from, particularly, the side of the driver seat can be switched.

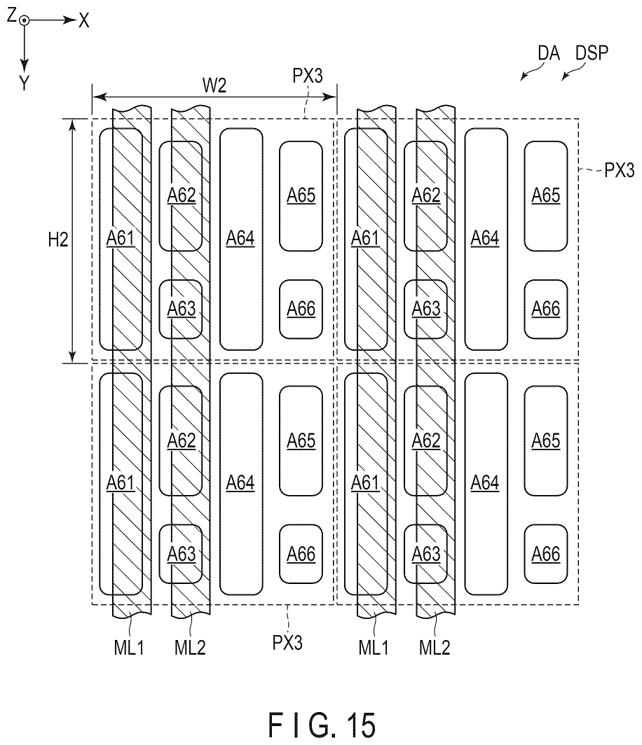

FIG. 15 is a diagram showing an example of a pixel applicable to the display device DSP shown in FIG. 13. The display device DSP comprises a pixel PX3 instead of the pixels PX1 and PX2 shown in FIG. 13. The plurality of pixels PX3 are provided in the entire surface of the display area DA, and are arranged in a matrix in the first direction X and the second direction Y.

The pixel PX3 includes the apertures A61 to A66. Each of the apertures A61 to A66 overlaps a plurality of display elements (not shown). As an example, a signal line is individually connected to the plurality of display elements, and each of the display elements is supplied with an individual image signal.

The relationship between a length W2, which is the length along the first direction X of one pixel PX3 of the pixels PX3 arranged in the first direction X, and a length H2, which is the length along the second direction Y of one pixel PX3 of the pixels PX3 arranged in the second direction Y, is represented as follows. In the illustrated example, the pixel PX3 has the same length along the first direction X and along the second direction Y. That is, the length W2 is equivalent to the length H2 (W2=H2).

As described above, in the display device DSP shown in FIG. 13, the resolution of a displayed image varies according to the modes. In contrast, in the display device DSP shown in FIG. 15, the length W2, which is the length along the first direction X of one pixel PX3 of the pixels PX3 arranged in the first direction X, is equivalent to the length H2, which is the length along the second direction Y of one pixel PX3 of the pixels PX3 arranged in the second direction Y. Therefore, a difference in the resolution between the modes decreases, improving the display quality.

FIG. 16 is a schematic plan view showing yet another example of the layout of the lenses ML1 and ML2. In the example shown in FIG. 16, the aperture A64 is adjacent to each of the apertures A65 and A66 in the first direction X and is adjacent to the aperture A61 in the second direction Y. In addition, the aperture A65 is adjacent to the aperture A64 in the first direction X and is adjacent to each of the apertures A63 and A66 in the second direction Y. In addition, the aperture A66 is adjacent to the aperture A64 in the first direction X and is adjacent to each of the apertures A62 and A65 in the second direction Y.

The plurality of pixels PX1 are repeatedly arranged in the first direction X. The plurality of pixels PX2 are repeatedly arranged in the first direction X. The row of the plurality of pixels PX1 arranged in the first direction X and the row of the plurality of pixels PX2 arranged in the first direction X are alternately arranged in the second direction Y. As an example, the number of the pixels PX1 arranged in the display area DA is almost equivalent to the number of the pixels PX2 arranged in the display area DA.

The relationship between a length W3, which is the length along the first direction X of one pixel PX1 of the pixels PX1 arranged in the first direction X, and a length H3, which is the length along the second direction Y of the pixels PX1 and PX2 adjacent to each other in the second direction Y, is represented as follows. In the illustrated example, the pixels PX1 and PX2 have the same length along the second direction Y. Further, the pixel PX1 has the same length along the first direction X and along the second direction Y. That is, the length H3 is approximately twice the height W3 (H3=2×W3).

The lenses ML1 and ML2 are provided every other pixel in the second direction Y. The lenses may be arranged by every m-pixels (m is an integer of two or more). In that case, the length H3 is approximately m-times of the height W3 (H3=m×W3).

The display device DSP shown in FIG. 16 can exhibit the same effects as those achieved by the display device DSP shown in FIG. 13.

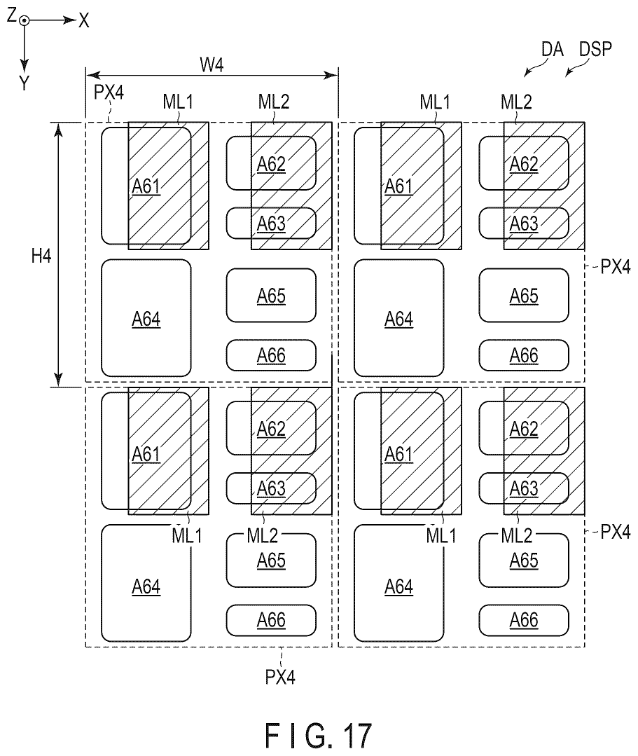

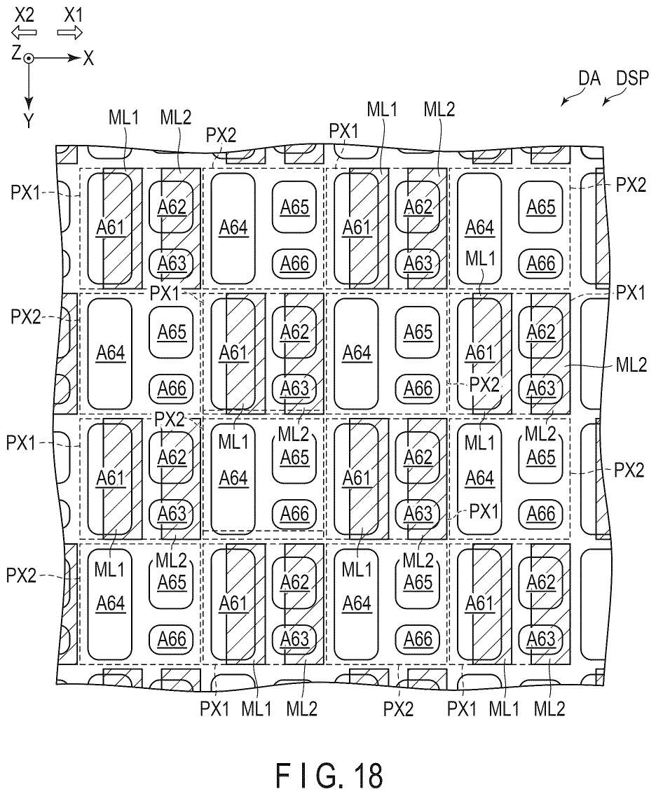

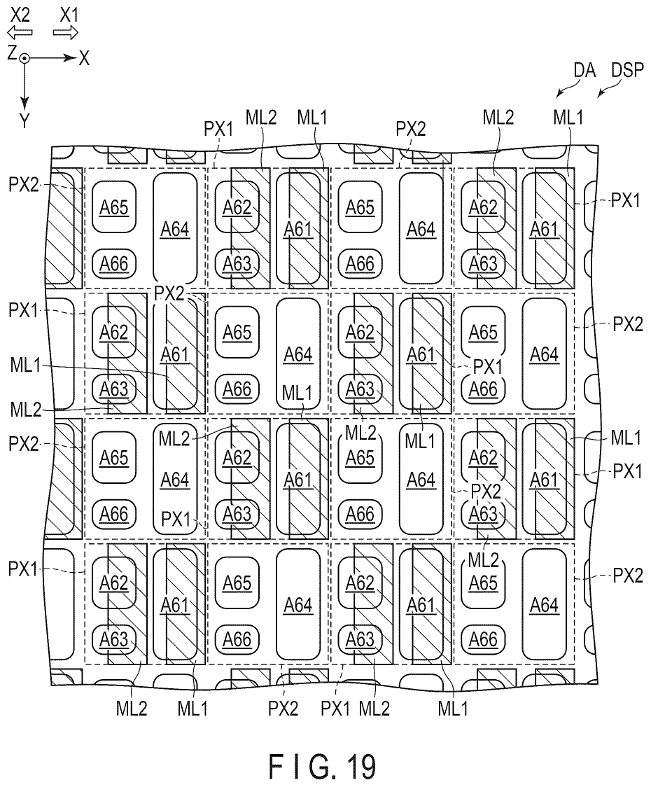

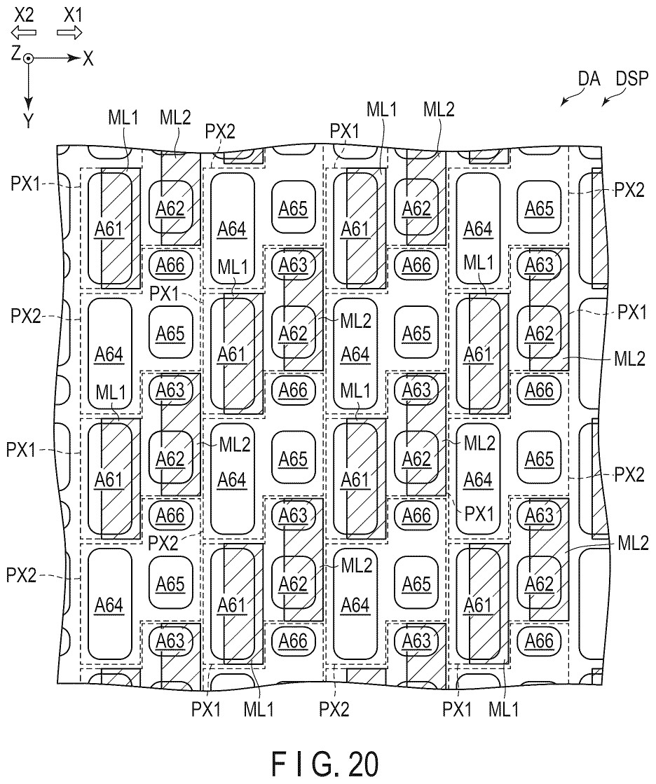

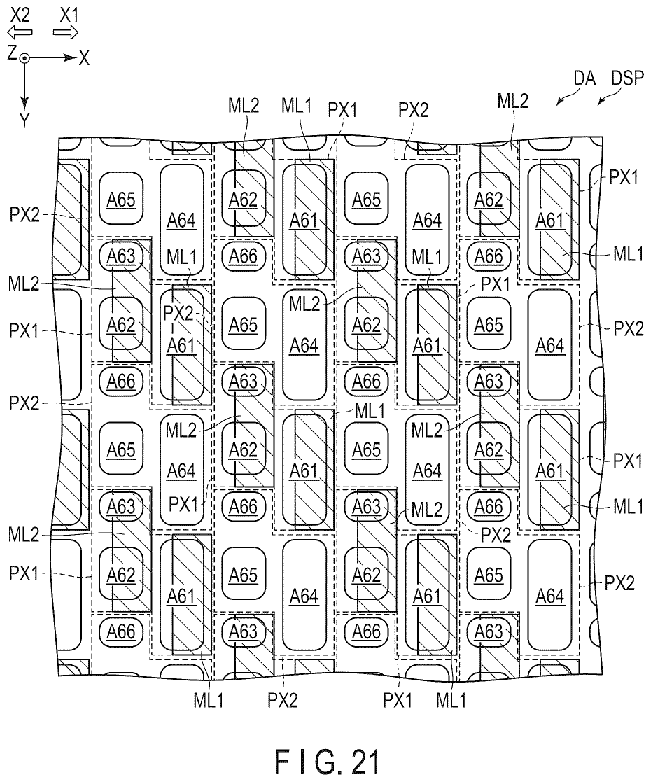

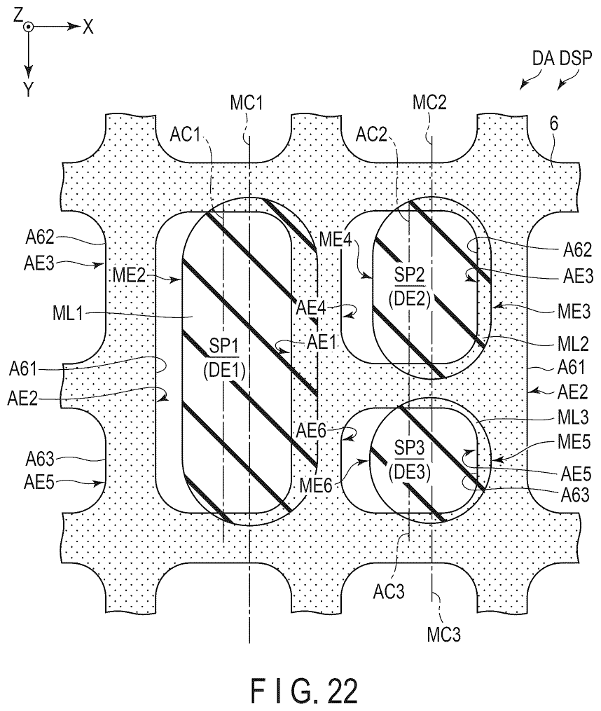

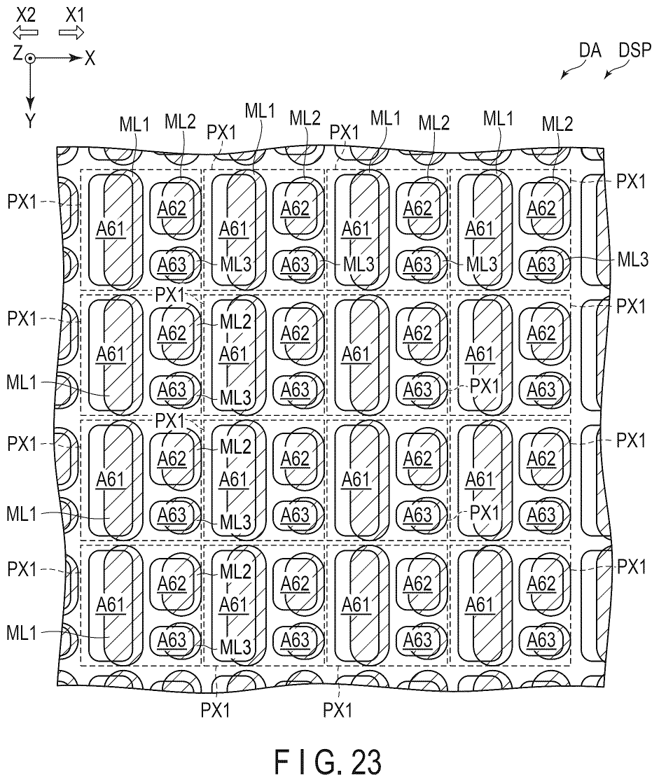

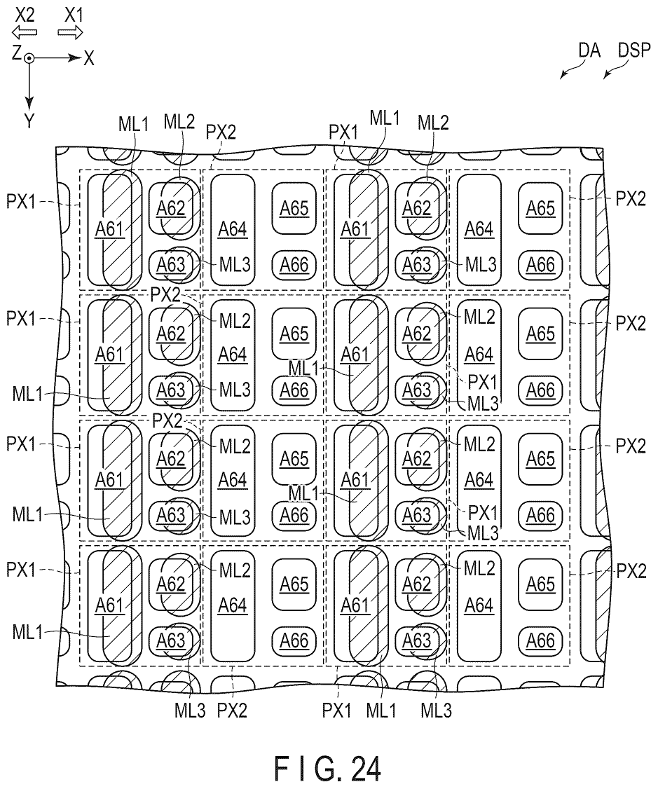

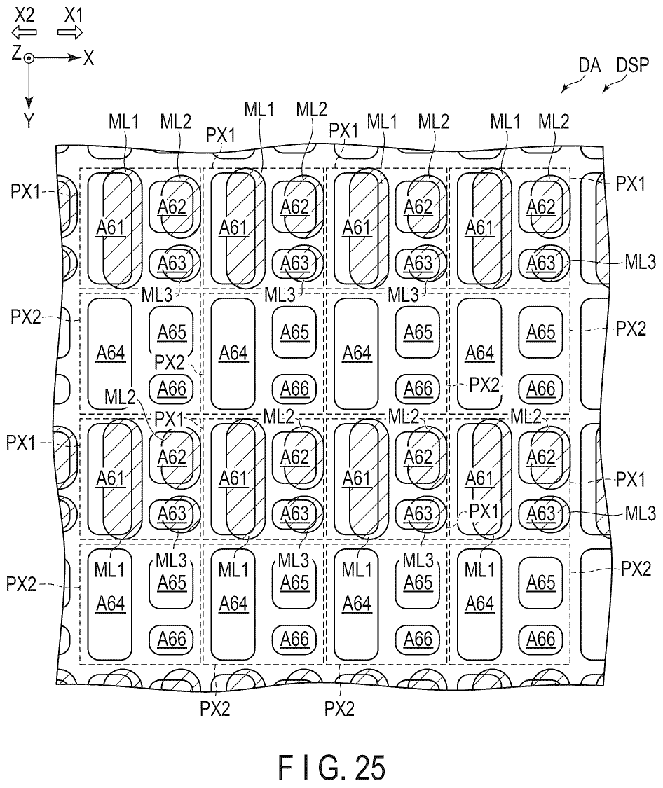

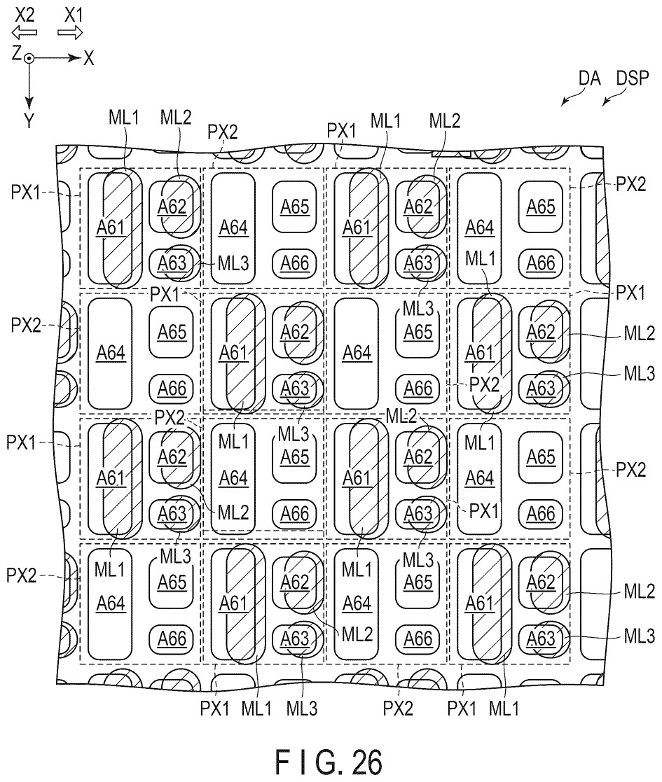

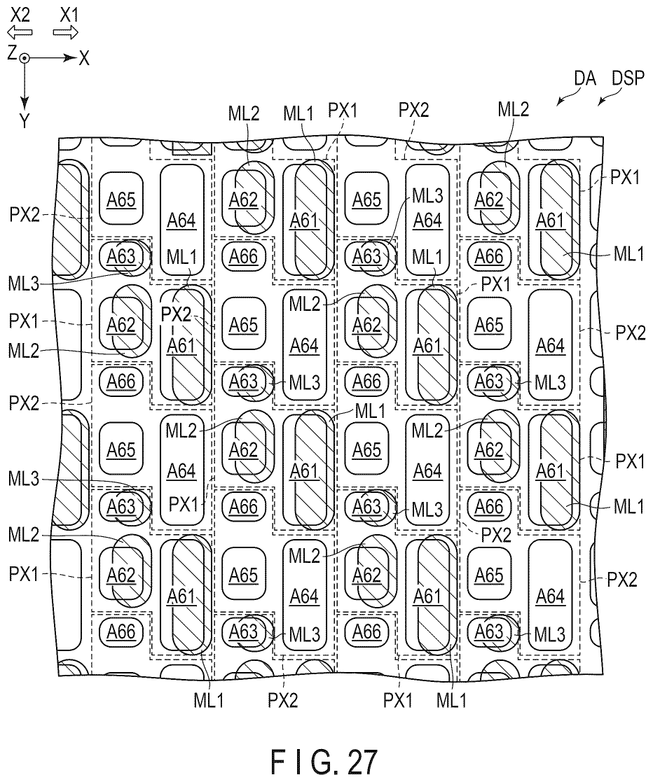

FIG. 17 is a diagram showing an example of a pixel applicable to the display device DSP shown in FIG. 16. The display device DSP comprises a pixel PX4 instead of the pixels PX1 and PX2 shown in FIG. 16. The plurality of pixels PX4 are provided in the entire surface of the display area DA, and are arranged in a matrix in the first direction X and the second direction Y.

The pixel PX4 includes the apertures A61 to A66. Each of the apertures A61 to A66 overlaps a plurality of display elements (not shown). As an example, a signal line is individually connected to the plurality of display elements, and each of the display elements is supplied with an individual image signal.

The relationship between a length W4, which is the length along the first direction X of one pixel PX4 of the pixels PX4 arranged in the first direction X, and a length H4, which is the length along the second direction Y of one pixel PX4 of the pixels PX4 arranged in the second direction Y, is represented as follows. In the illustrated example, the pixel PX4 has the same length along the first direction X and along the second direction Y. That is, the length W4 is equivalent to the length H4 (W4=H4).

The display device DSP shown in FIG. 17 can exhibit the same effects as those achieved by the display device DSP shown in FIG. 15.

FIG. 18 is a schematic plan view showing still another example of the layout of the lenses ML1 and ML2. The plurality of pixels PX1 and the plurality of pixels PX2 are alternately arranged in the first direction X and the second direction Y. The length along the first direction X of the adjacent pixels PX1 and PX2, of the pixels PX1 and PX2 that are alternately arranged in the first direction X, is equivalent to the length along the second direction Y of the adjacent pixels PX1 and PX2, of the pixels PX1 and PX2 that are alternately arranged in the second direction Y. Therefore, similarly to the display devices DSP shown in FIG. 15 and FIG. 17, a difference in the resolution between the modes can decrease.

The display device DSP shown in FIG. 18 can exhibit the same effects as those achieved by the display device DSP shown in FIG. 13.

FIG. 19 is a schematic plan view showing still another example of the layout of the lenses ML1 and ML2. The arrangement of the apertures A61 to A66 and the lenses ML1 and ML2 shown in FIG. 19 is a reverse with respect to the second direction Y of the arrangement of the apertures A61 to A66 and the lenses ML1 and ML2 shown in FIG. 18.

The display device DSP shown in FIG. 19 can exhibit the same effects as those achieved by the display device DSP shown in FIG. 13.

FIG. 20 is a schematic plan view showing still another example of the layout of the lenses ML1 and ML2.

In the example shown in FIG. 20, the aperture A61 is adjacent to each of the apertures A62, A63, A65, and A66 in the first direction X and is adjacent to the aperture A64 in the second direction Y. In addition, the aperture A62 is adjacent to each of the apertures A61 and A64 in the first direction X and is adjacent to each of the apertures A63 and A66 in the second direction Y. Further, the aperture A63 is adjacent to each of the apertures A61 and A64 in the first direction X and is adjacent to each of the apertures A62 and A65 in the second direction Y.

In the example shown in FIG. 20, the aperture A64 is adjacent to each of the apertures A62, A63, A65, and A66 in the first direction X and is adjacent to the aperture A61 in the second direction Y. In addition, the aperture A65 is adjacent to each of the apertures A61 and A64 in the first direction X and is adjacent to each of the apertures A63 and A66 in the second direction Y. Further, the aperture A66 is adjacent to each of the apertures A61 and A64 in the first direction X and is adjacent to each of the apertures A62 and A65 in the second direction Y.

The plurality of pixels PX1 in which the apertures A61, A62, and A63 are provided in the above manner and the plurality of pixels PX2 in which the apertures A64, A65, and A66 are provided in the above manner are alternately arranged in the first direction X and the second direction Y.

The display device DSP shown in FIG. 20 can exhibit the same effects as those achieved by the display device DSP shown in FIG. 18.

FIG. 21 is a schematic plan view showing still another example of the layout of the lenses ML1 and ML2. The arrangement of the apertures A61 to A66 and the lenses ML1 and ML2 shown in FIG. 21 is the arrangement reversed with respect to the second direction Y of the apertures A61 to A66 and the lenses ML1 and ML2 shown in FIG. 20.

The display device DSP shown in FIG. 21 can exhibit the same effects as those achieved by the display device DSP shown in FIG. 13.

FIG. 22 is a plan view showing an example of the layout of the apertures A61, A62, and A63 of the partition 6 and the lenses ML1 and ML2, and a lens ML3. The display device DSP further comprises a lens ML3 (a third lens).

In the illustrated example, in plan view, the lens ML1 is formed to have a shape constituted by the lens edges ME1 and ME2 that are parallel to the second direction Y and two semicircular arcs extending outside of the lens ML1 in the second direction Y. Further, in plan view, the lens ML2 has a shape constituted by the lens edges ME3 and ME4 that are parallel to the second direction Y and two semicircular arcs extending outside of the lens ML2 in the second direction Y. The lenses ML1 and ML2 may have an elliptic shape or a circular shape in plan view.

In the illustrated example, the lens ML3 has a circular shape in plan view. In plan view, the lens ML3 may have a shape constituted by a straight line parallel to the first direction X and two semicircular arcs extending outside of the lens ML3 in the first direction X. Alternatively, the lens ML3 may have an elliptic shape.

The lens ML1 has a convex shape projecting toward a side opposite to the aperture A61 in the third direction Z. The lens ML2 has a convex shape projecting toward a side opposite to the aperture A62 in the third direction Z. The lens ML3 has a convex shape projecting toward a side opposite to the aperture A63 in the third direction Z.

The lens ML3 overlaps a part of the aperture A63. The lens ML3 has lens edges ME5 and ME6 and a lens center line MC3 (a third lens center line). The lens edges ME5 and ME6 are intersections of a straight line and the circumference of the lens ML3, the straight line passing through the center of the circular lens ML3 and being parallel to the first direction X. In a case where the lens ML3 does not have a circular shape in plan view, each of the lens edges ME5 and ME6 may be a straight line parallel to the second direction Y. In the illustrated example, the lens edge ME5 overlaps the partition 6 in plan view and is located between the aperture edge AE2 and the aperture edge AE5 in the first direction X. In addition, the lens edge ME6 overlaps the aperture A63 in plan view and is located between the aperture edge AE6 and the center line AC3 in the first direction X. The lens ML3 covers not the aperture edge AE6 but the aperture edge AE5. The lens center line MC3 is parallel to the second direction Y. The lens center line MC3 is located between the center line AC3 and the aperture edge AE5 in plan view.

In the illustrated example, the lens ML3 does not completely cover the aperture A63 in the first direction X. However, unlike this example, the lens ML1 may completely cover the aperture A63.

FIG. 23 is a schematic plan view showing an example of the layout of the lenses ML1, ML2, and ML3. The arrangement pattern of the pixels PX1 in FIG. 23 is the same as the arrangement pattern of the pixels PX1 in FIG. 12. The lenses ML1, ML2, and ML3 respectively overlap the apertures A61, A62, and A63 of the plurality of pixels PX1.

The display device DSP shown in FIG. 23 can exhibit the same effects as those achieved by the display device DSP shown in FIG. 12.

FIG. 24 is a schematic plan view showing another example of the layout of the lenses ML1, ML2, and ML3. The arrangement pattern of the pixels PX1 and PX2 in FIG. 24 is the same as the arrangement pattern of the pixels PX1 and PX2 in FIG. 13. The lenses ML1, ML2, and ML3 respectively overlap the apertures A61, A62, and A63 of the plurality of pixels PX1, but do not respectively overlap the apertures A64, A65, and A66 of the plurality of pixels PX2.

The display device DSP shown in FIG. 24 can exhibit the same effects as those achieved by the display device DSP shown in FIG. 13.

FIG. 25 is a schematic plan view showing yet another example of the layout of the lenses ML1, ML2, and ML3. The arrangement pattern of the pixels PX1 and PX2 in FIG. 25 is the same as the arrangement pattern of the pixels PX1 and PX2 in FIG. 16.

The display device DSP shown in FIG. 25 can exhibit the same effects as those achieved by the display device DSP shown in FIG. 16.

FIG. 26 is a schematic plan view showing still another example of the layout of the lenses ML1, ML2, and ML3. The arrangement pattern of the pixels PX1 and PX2 in FIG. 26 is the same as the arrangement pattern of the pixels PX1 and PX2 in FIG. 18.

The display device DSP shown in FIG. 26 can exhibit the same effects as those achieved by the display device DSP shown in FIG. 18.

FIG. 27 is a schematic plan view showing still another example of the layout of the lenses ML1, ML2, and ML3. The arrangement pattern of the pixels PX1 and PX2 in FIG. 27 is the same as the arrangement pattern of the pixels PX1 and PX2 in FIG. 21.

The display device DSP shown in FIG. 27 can exhibit the same effects as those achieved by the display device DSP shown in FIG. 21.

All of the display devices that can be implemented by a person of ordinary skill in the art through arbitrary design changes to the display device described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a substrate;
a plurality of light emitting elements provided above the substrate;
a lower portion surrounding each of the plurality of light emitting elements;
an upper portion provided above the lower portion and including a first aperture surrounded by an edge portion projecting from a side surface of the lower portion; and
a first lens overlapping at least a part of the first aperture and having a convex shape projecting toward a side opposite to the first aperture, wherein
the edge portion includes a first aperture edge and a second aperture edge that face each other in a first direction and are parallel to a second direction intersecting the first direction,
the plurality of light emitting elements include a first light emitting element overlapping the first aperture,
the first aperture has a first center line parallel to the second direction and equidistant from the first aperture edge and the second aperture edge along the first direction,
the first lens includes a first lens center line parallel to the second direction, and
the first lens center line is located between the first center line and the first aperture edge.

2. The display device of claim 1, wherein
the upper portion further includes a second aperture adjacent to the first aperture in the first direction and surrounded by the edge portion,
the display device further comprises a second lens overlapping at least a part of the second aperture and having a convex shape projecting toward a side opposite to the second aperture, and
the edge portion includes a third aperture edge and a fourth aperture edge that face each other in the first direction and are parallel to the second direction,
the plurality of light emitting elements include a second light emitting element overlapping the second aperture,
the second aperture has a second center line parallel to the second direction and equidistant from the third aperture edge and the fourth aperture edge along the first direction,
the second lens has a second lens center line parallel to the second direction, and
the second lens center line is located between the second lens center line and the third aperture edge.

3. The display device of claim 2, wherein
the upper portion further includes a third aperture adjacent to the second aperture in the second direction and surrounded by the edge portion,
the display device further comprises a third lens overlapping at least a part of the third aperture and having a convex shape projecting toward a side opposite to the third aperture, and
the edge portion includes a fifth aperture edge and a sixth aperture edge that face each other in the first direction and are parallel to the second direction,
the plurality of light emitting elements include a third light emitting element overlapping the third aperture,
the third aperture has a third center line parallel to the second direction and equidistant from the fifth aperture edge and the sixth aperture edge along the first direction,
the third lens has a third lens center line parallel to the second direction, and
the third lens center line is located between the third center line and the fifth aperture edge.

4. The display device of claim 2, wherein
the upper portion further includes a third aperture adjacent to the second aperture in the second direction and surrounded by the edge portion,
the edge portion includes a fifth aperture edge and a sixth aperture edge that face each other in the first direction and are parallel to the second direction,
the plurality of light emitting elements include a third light emitting element overlapping the third aperture,
the third aperture has a third center line parallel to the second direction and equidistant from the fifth aperture edge and the sixth aperture edge along the first direction,
the second lens continuously overlaps the second aperture and the third aperture, and
the second lens center line is located between the third center line and the fifth aperture edge.

5. The display device of claim 4, further comprising:
a plurality of first pixels, wherein
each of the plurality of first pixels includes the first aperture, the second aperture, and the third aperture, the plurality of first pixels being repeatedly arranged in the second direction, and
the first lens and the second lens continuously overlap the plurality of first pixels.

6. The display device of claim 3, wherein
the upper portion further includes:
a fourth aperture adjacent to the first aperture in the second direction;
a fifth aperture adjacent to the fourth aperture in the first direction; and
a sixth aperture adjacent to the fifth aperture in the second direction, and
the fourth aperture, the fifth aperture, and the sixth aperture do not overlap the first lens, the second lens, and the third lens.

7. The display device of claim 4, wherein
the upper portion further includes:
a fourth aperture adjacent to the first aperture in the second direction;
a fifth aperture adjacent to the fourth aperture in the first direction; and
a sixth aperture adjacent to the fifth aperture in the second direction, and
the fourth aperture, the fifth aperture, and the sixth aperture do not overlap the first lens and the second lens.

8. The display device of claim 4, wherein
the upper portion further includes:
a fourth aperture adjacent to the third aperture in the first direction;
a fifth aperture adjacent to the fourth aperture in the first direction; and
a sixth aperture adjacent to the fifth aperture in the second direction, and
the fourth aperture, the fifth aperture, and the sixth aperture do not overlap the first lens and the second lens.

9. The display device of claim 6, further comprising:
a plurality of first pixels and a plurality of second pixels, wherein
each of the plurality of first pixels includes the first aperture, the second aperture, and the third aperture,
each of the plurality of second pixels includes the fourth aperture, the fifth aperture, and the six aperture, and
the first pixel and the second pixel are alternately arranged in the second direction.

10. The display device of claim 1, wherein
the first lens covers the first aperture in the second direction.

11. The display device of claim 1, wherein
the first lens covers the first aperture.

12. The display device of claim 2, further comprising:
a light-shielding layer covering a portion between the first lens and the second lens.

13. The display device of claim 2, wherein
the first lens is in contact with the second lens.

14. The display device of claim 1, wherein
the first lens has a flat surface at an apex portion of the first lens.

15. The display device of claim 1, wherein
the first lens has a section asymmetric with respect to the first lens center line.

16. The display device of claim 1, further comprising:
a first organic insulating layer provided on the first light emitting element;
a sealing layer provided on the first organic insulating layer; and
a second organic insulating layer provided between the sealing layer and the first lens, wherein
the second organic insulating layer is thicker than the first organic insulating layer.

17. The display device of claim 16, further comprising:
a color filter layer provided between the second organic insulating layer and the first lens.

18. The display device of claim 1, wherein
the first light emitting element includes a light emitting layer formed of a material emitting green-colored light or blue-colored light.

19. The display device of claim 3, wherein
an area of the first aperture is greater than an area of the second aperture and an area of the third aperture in plan view.

20. The display device of claim 1, wherein
the first lens is formed of a transparent resin material.
